(19) United States
(12) Patent Application Publication
(10) Pub. No.: US 2009/0271974 A1
(43) Pub. Date: Nov. 5, 2009

(54) Transportable Switching Station for a Magnetic Levitation Railroad System

(75) Inventors: Wilfried Glaubitz, Neunkirchen (DE); Jürgen Gress, Lauf (DE); Wolfgang Spaeth, Erlangen (DE)

Correspondence Address: LERNER GREENBERG STEMER LLP, P O BOX 2480, HOLLYWOOD, FL, 33022-2480, US

(73) Assignee: SIEMENS AKTIENGESELLSCHAFT, Munchen (DE)

(21) Appl. No.: 12/302,909

(22) PCT Filed: May 31, 2006
(86) PCT No.: PCT/DE2006/000974

§ 371 Date: Dec. 1, 2008

(51) Int. Cl. H05K 13/04

(52) U.S. Cl. 29/729; 29/762

(57) ABSTRACT

A device for switching stator sections that are arranged on both sides of a guideway, for instance of a magnetic levitation railway system. In order for the device to be installed in as independent a manner as possible, the separately installed switching stations comprise not more than three switchboard sections each and are associated with only one stator section. The switching sections are therefore more compact and less heavy.

The invention relates to an apparatus for switching stator sections which are arranged on both sides of a track for a magnetic levitation vehicle.

An apparatus such as this is already known from the common prior art. In the magnetic levitation railroad systems that have already been implemented in practice, the drive for the magnetic levitation vehicle is arranged in the track. On each of its two sides, the track has stator sections with a length of up to 2 km, which can be connected via stator section switches to a section cable, which is fed by a converter. In this case, the stator sections are arranged one behind the other in a chain. The section cable is connected and disconnected in synchronism of the vehicle, so that the only stator section which is in each case supplied with power is that in which the magnetic levitation vehicle is currently located. In order to avoid having to accept drive losses when moving over a stator section boundary, the stator sections are arranged offset with respect to one another on the two sides of the track. The stator sections are normally 3-phase stator windings which are connected at their end remote from the section cable, to form a start point. In this case, each stator winding is arranged between a star-point switch and a stator feed switch, with the star point following the star-point switch in the direction of the power flow. A grounding switch is used to ground the star point for maintenance purposes for the magnetic levitation railroad system. According to the prior art, the switches which are required for connection of the stator sections are accommodated in a switching station which is positioned in the vicinity of the track. Each switching station is intended for connection and disconnection of two stator sections which are arranged on different sides of the track. According to the prior art, the switching station therefore comprises two stator star-former panels in which the star-point switches and, if required, a grounding switch are arranged. Furthermore, two stator feed panels are provided with stator feed switches. Finally, two cable input panels are provided in order to allow maintenance work on the switching station. In the cable input panels, isolating switches which open when no current flows are used to interrupt the galvanic connection between the power-feeding section cable and the switching station. A total of six switch panels are therefore arranged within one switching station, according to the prior art. The abovementioned switching station is therefore space-consuming and has a high intrinsic weight. A robust foundation and a special approach road are required for positioning of the switching stations, with the approach route allowing the delivery of the switching stations by means of transport vehicles of appropriate size.

The object of the present invention is to provide a switching station of the type mentioned initially which can be positioned as independently of the location as possible.

The invention achieves this object by an apparatus having individually positioned switching stations which each have no more than three switch panels, wherein each switch panel can be connected to a single stator section.

The apparatus according to the invention comprises separately positioned switching stations which, in contrast to the prior art, are no longer associated with two stator sections at the same time. According to the invention, each switching station is associated only with a maximum of two adjacent stator sections which, for example, extend along a single side of a track of magnetic a levitation railroad. Each switching station therefore has no more than three switch panels, as a result of which the switching station according to the invention is considerably more compact than the already known switching station. For this reason, the apparatus according to the invention can be positioned at virtually any desired location, for example very close to the track, thus avoiding relatively long cable lines between the switching station and the stator section, as normal in the prior art. A further advantage of the apparatus according to the invention is the better maintenance capability. The more compact design not only simplifies positioning and mounting of the switching station during commissioning of the magnetic levitation railroad system that, furthermore, also allows maintenance by replacement of faulty components. For example, within the scope of the invention, it is possible to completely replace all the switch panels in the switching station in a simple manner, with the new switch panels having already been tested and licensed before being fitted. Because of the reduced weight, the switch panels can be transported more easily and, for example, they can be transported using the track itself. These advantages outweigh the obvious disadvantage of the invention, specifically that twice as many switching stations are required as according to the prior art.

Each switching station advantageously has a mounting plate for supporting the switch panels. The mounting plate makes it even easier to fit the switch panels. In this case, a mounting plate with an aperture opening is advantageous, making it easier to insert input and output lines into the switching station. This mounting plate is, for example, perforated in order to prevent the formation of standing water.

The switch panels of the apparatus according to the invention are expediently connected to one another by holding means. By way of example, holding means such as these comprise a common switch panel bracing, a roof which covers the top of the switch panels, and a base in the lower area of the switch panels. panel is connected upstream of the other switch panels, in the direction of the power flow. The stator panel comprises the stator feed switches for connection of the associated stator section to the section cable during normal operation. During normal operation, the isolation switches for the cable feed panel are in their contact position. Star-point switches which allow the start point to be formed for the stator section when the contact position, are arranged in the stator star-former panel. In this case, by way of example, the stator section is in the form of a three-phase stator windings. However, the stator star-former panel is not associated with the same stator section as the stator feed panel and the cable input panel. In fact, the stator star-former panel is associated with an immediately adjacent section, wherein the stator sections are arranged in series with one another, in a chain. Furthermore, a grounding switch is provided in order to ground the star point in the stator star-former panel.

An auxiliary power supply is advantageously provided in one of the switch panels. An auxiliary power supply is required for closed-loop control, monitoring or open-loop control of the switches, switch-position indicators and other appliances, in order to allow the magnetic levitation vehicle to be driven smoothly. According to the prior art this power supply is accommodated in a separate housing. According to the invention, the splitting of the switching stations between the respective sides of the track results in sufficient space, in particular in the cable input panel, to allow the auxiliary power supply to be accommodated in the switching station.

The switch panels advantageously have essentially the same dimensions. According to this advantageous further development, any desired combinations of switching stations are possible, with the mounting platform and holding means remaining the same. In addition, the installation per se is the same for all the switching stations.

The mounting plate expediently has means for holding cable ends. The means, or in other words, the holders, make it easy to replace all the switch panels. All that is necessary for maintenance is to detach the connections between the permanently laid cables and the components of the switch panels. All the switch panels can then be removed from the mounting plate completely, for example using a crane, and a new, already tested, switching station group can then be installed. During this process, the holders hold the cable ends in the desired position when the switching stations are removed. By way of example, this can expediently be done at night, that is to say during a rest phase in train operation.

Further expedient refinements and advantages of the invention are the subject matter of the following description of exemplary embodiments of the invention with reference to the figures of the drawing, in which the same reference symbols refer to components having the same effect, and in which:

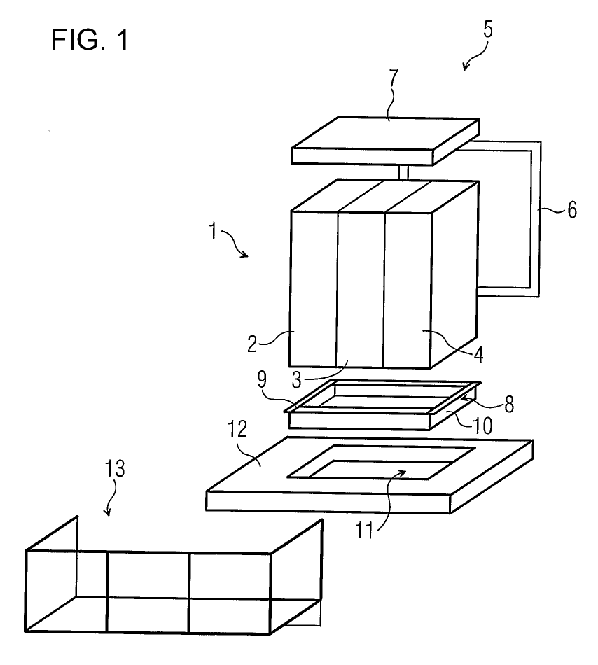

FIG. 1 shows one exemplary embodiment of the apparatus according to the invention,

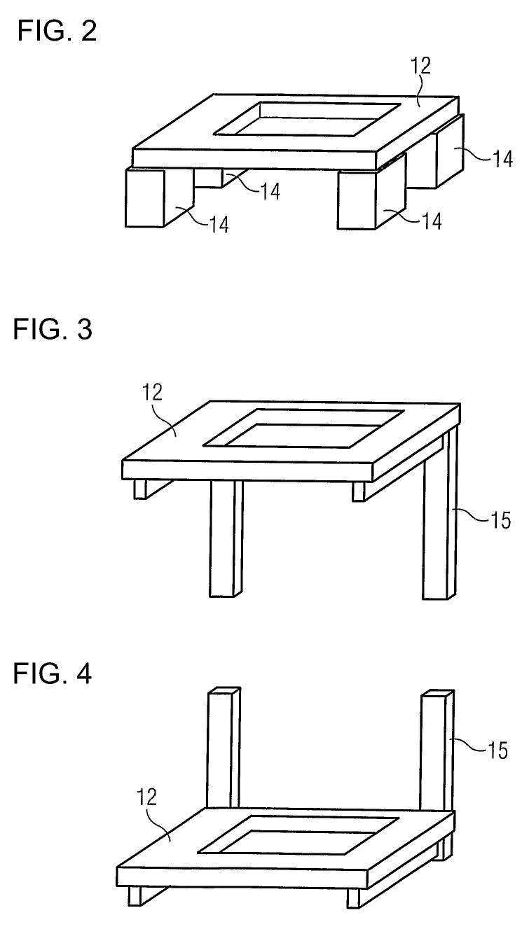

FIG. 2 shows the installation of the apparatus according to the invention on the ground, and

FIGS. 3 to 5 show the installation of the apparatus according to the invention on a supporting structure.

FIG. 1 shows one exemplary embodiment of a switching station 1 of the apparatus according to the invention, wherein the switching station 1 comprises a cable input panel 2, a stator feed panel 3 and a stator star-former panel 4. This apparatus is used for connection and disconnection of stator sections, which are not illustrated, to and from a power supply. The stator sections and the power supply are part of a magnetic levitation railroad system. The housings of the three switch panels 2, 3, 4 are connected to one another via connection means 5, wherein the connection means 5 comprise cabinet bracing 6 as well as a roof 7 and a base 8. The cabinet bracing 6 is detachably screwed to the housings of the switch panels 2, 3 and 4 by means of expedient screw connections. The switch panels 2, 3, 4 are made stable in the upper area by pushing on the roof 7, which is designed to accurately fit the upper area of the switch panel housings. The base 8 has a circumferentially closed surrounding collar section 9, which can likewise be connected to the housing of the switch panels 2, 3, 4, by expedient screw connections. This also makes the lower area more robust. The base 8 furthermore also has a likewise closed surrounding push-in section 10 which is designed to accurately fit a centre opening 11 which is bounded by a mounting plate 12. The center opening 11 allows permanently laid cables to be passed through the mounting plate 12 into the switch panels 2, 3 and 4. In order to allow maintenance work to be carried out in the event of a fault, even at installation locations where access is difficult, a working platform 13 with a railing is provided, with the mounting plate 12 having means for attachment of the working platform, although these means are not illustrated in the figure in FIG. 1.

FIG. 2 shows the installation of the apparatus as shown in FIG. 1 on the ground. Simple base foundations 14 are used for this purpose and are incorporated in an expediently prepared base in the vicinity of a track of the magnetic levitation vehicle. The mounting plate 12 is manufactured, for example, from steel and is simply placed on the base foundations 14, which are aligned with respect to one another, and is held there by its own weight.

FIGS. 3 and 4 show alternative installation options. For example, it is possible to attach the mounting plate 12 to a wall or to a pillar such that it is suspended or is standing. Expedient attachment means 15 are required for this purpose, concrete holders, positioned at right angles, in the illustrated exemplary embodiments.

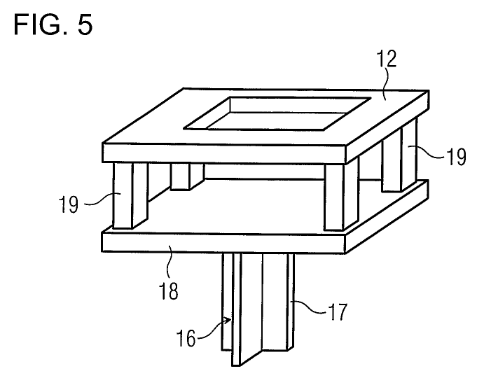

FIG. 5 shows the installation of mounting plate 12 on a free-standing post 16, which has a pillar section 17 and a supporting section 18. Supporting foundations 19 are in turn arranged on the supporting section 18, and are used to support the mounting plate 12. The switch panels are then positioned as explained in conjunction with FIG. 1.

1-10. (canceled)

11. An apparatus for switching stator sections disposed on mutually opposite sides of a track for a magnetic levitation vehicle, comprising:
individually positioned switching stations each having no more than three switch panels; and
wherein each said switch panel can be connected to a single stator section.

12. The apparatus according to claim 11, wherein each said switching station has a mounting plate for supporting said switch panels.

13. The apparatus according to claim 11, which comprises means for mounting a working platform.

14. The apparatus according to claim 12, wherein said mounting plate is configured to be supported on base foundations.

15. The apparatus according to claim 12, wherein said mounting plate is attached to a supporting structure.

16. The apparatus according to claim 11, wherein said switch panels comprise at least one panel selected from the group consisting of a cable input panel, a stator feed panel, and a stator star-former panel.

17. The apparatus according to claim 16, wherein said stator star-former panel is associated with a stator section arranged immediately adjacent said stator section associated with said stator feed panel.

18. The apparatus according to claim 11, which comprises an auxiliary power supply in one of said switch panels.

19. The apparatus according to claim 11, wherein said switch panels have substantially identical dimensions.

20. The apparatus according to claim 12, wherein said mounting plate includes means for holding cable ends.
